(19) United States
(12) Patent Application Publication
(10) Pub. No.: US 2025/0013035 A1
(43) Pub. Date: Jan. 9, 2025

(54) OPTICAL REFLECTIVE ELEMENT

(71) Applicant: Panasonic Intellectual Property Management Co., Ltd., Osaka (JP)

(72) Inventors: Jun TAKIGAWA, Osaka (JP); Kensuke MIHARA, Osaka (JP)

(21) Appl. No.: 18/892,660

(22) Filed: Sep. 23, 2024

Related U.S. Application Data
(63) Continuation of application No. PCT/JP2023/003969, filed on Feb. 7, 2023.

(30) Foreign Application Priority Data
Mar. 23, 2022 (JP) 2022-047382

(51) Int. Cl. G02B 26/08

(52) U.S. Cl. CPC G02B 26/0816

(57) ABSTRACT

An optical reflective element includes: a movable part having a mirror formed therein; a fixation part supporting the movable part; a meander-type vibration plate placed between the movable part and the fixation part; a coupling beam coupling the vibration plate to the movable part; a drive part placed on the vibration plate and configured to rotate the movable part about a rotation axis; and a stopper placed adjacent to at least one of the vibration plate and the coupling beam in a direction parallel to the rotation axis and configured to restrict at least displacement of the vibration plate.

### CROSS REFERENCE TO RELATED APPLICATION

This application is a continuation of International Application No. PCT/JP2023/003969 filed on Feb. 7, 2023, entitled “OPTICAL REFLECTIVE ELEMENT”, which claims priority under 35 U.S.C. Section 119 of Japanese Patent Application No. 2022-047382 filed on Mar. 23, 2022, entitled “OPTICAL REFLECTIVE ELEMENT”. The disclosures of the above applications are incorporated herein by reference.

### BACKGROUND OF THE INVENTION

### Field of the Invention

The present invention relates to an optical reflective element that rotates a movable part having a mirror formed therein, about a rotation axis.

### Description of Related Art

An optical reflective element in which a movable part having a mirror formed therein is rotated about a rotation axis by a drive part placed on a meander-type vibration plate has been known. In this type of optical reflective element, a stopper is provided to prevent each part of the optical reflective element from being displaced more than necessary when an impact is applied from the outside. For example, Japanese Laid-Open Patent Publication No. 2012-145910 describes a structure including: an element having meander-type vibration plates and a movable part having a mirror formed therein; a fixing support member to which the element is adhered and fixed; and a cover covering and housing the element and the fixing support member. A stopper for impact resistance is provided to each of the fixing support member placed below the element and the cover above the element. Accordingly, when a vertical impact is applied to the element due to drop or the like, the element is protected from the impact.

In the above structure, when an impact is applied in a direction parallel to the rotation axis of the movable part, a force proportional to the masses of the movable part and the vibration plates is generated in the direction of the impact. In this case, stress may be concentrated on a connection part connecting the adjacent vibration plates, so that the element may be damaged.

### SUMMARY OF THE INVENTION

A main aspect of the present invention is directed to an optical reflective element. The optical reflective element according to this aspect includes: a movable part having a mirror formed therein; a fixation part supporting the movable part; a meander-type vibration plate placed between the movable part and the fixation part; a coupling beam coupling the vibration plate to the movable part; a drive part placed on the vibration plate and configured to rotate the movable part about a rotation axis; and a stopper placed adjacent to at least one of the vibration plate and the coupling beam in a direction parallel to the rotation axis and configured to restrict at least displacement of the vibration plate.

In the optical reflective element according to this aspect, the stopper is placed adjacent to at least one of the vibration plate and the coupling beam in the direction parallel to the rotation axis. Accordingly, when an impact is applied to the optical reflective element in the direction parallel to the rotation axis, displacement of the vibration plate is restricted by the stopper. Therefore, the impact resistance of the optical reflective element in the direction parallel to the rotation axis of the movable part can be improved.

The effects and the significance of the present invention will be further clarified by the description of the embodiments below. However, the embodiments below are merely examples for implementing the present invention. The present invention is not limited to the description of the embodiments below in any way.

### BRIEF DESCRIPTION OF THE DRAWINGS

FIG. 1 is a plan view schematically showing a configuration of an optical reflective element according to Embodiment 1;

FIG. 2 is a side view schematically showing a C1-C2 cross-section of FIG. 1 according to Embodiment 1;

FIG. 3 is a side view schematically showing a C3-C4 cross-section of FIG. 1 according to Embodiment 1;

FIG. 4 shows simulation results of maximum stress when an impact is applied in an X-axis direction, according to Comparative Examples 1 and 2 and Embodiment 1;

FIG. 5A is a plan view schematically showing a configuration of an optical reflective element according to Modification 1 of Embodiment 1;

FIG. 5B is a plan view schematically showing a configuration of an optical reflective element according to Modification 2 of Embodiment 1;

FIG. 6A is a plan view schematically showing a configuration of an optical reflective element according to Modification 3 of Embodiment 1;

FIG. 6B is a plan view schematically showing a configuration of an optical reflective element according to Modification 4 of Embodiment 1;

FIG. 7 is a plan view schematically showing a configuration of an optical reflective element according to Modification 5 of Embodiment 1;

FIG. 8 is a plan view schematically showing a configuration of an optical reflective element according to Embodiment 2;

FIG. 9 is a plan view schematically showing a configuration of an optical reflective element according to a modification of Embodiment 2;

FIG. 10 is a plan view schematically showing a configuration of an optical reflective element according to Embodiment 3;

FIG. 11 is a side view schematically showing a C5-C6 cross-section of FIG. 10 according to Embodiment 3;

FIG. 12A is a plan view schematically showing a configuration of an optical reflective element according to Modification 1 of Embodiment 3;

FIG. 12B is a plan view schematically showing a configuration of an optical reflective element according to Modification 2 of Embodiment 3;

FIG. 13 is a plan view schematically showing a configuration of an optical reflective element according to Embodiment 4; and

FIG. 14 is a plan view schematically showing a configuration of an optical reflective element according to a modification of Embodiment 4.

It is noted that the drawings are solely for description and do not limit the scope of the present invention in any way.

### DETAILED DESCRIPTION

Hereinafter, embodiments of the present invention will be described with reference to the drawings. For convenience, in each drawing, X, Y, and Z axes that are orthogonal to each other are additionally shown. The Z-axis positive direction is the vertical upward direction.

In each embodiment, an optical reflective element that performs scanning with a beam incident on a reflection surface by rotation of the reflection surface is described. This optical reflective element is installed, for example, in an image display device that displays a predetermined image by scanning with a beam. However, the device in which the optical reflective element is installed is not limited thereto. For example, an optical reflective element having the following configuration may be installed in an object detection device that detects the presence or absence of an object in the projection direction of a beam and the distance to an object.

### Embodiment 1

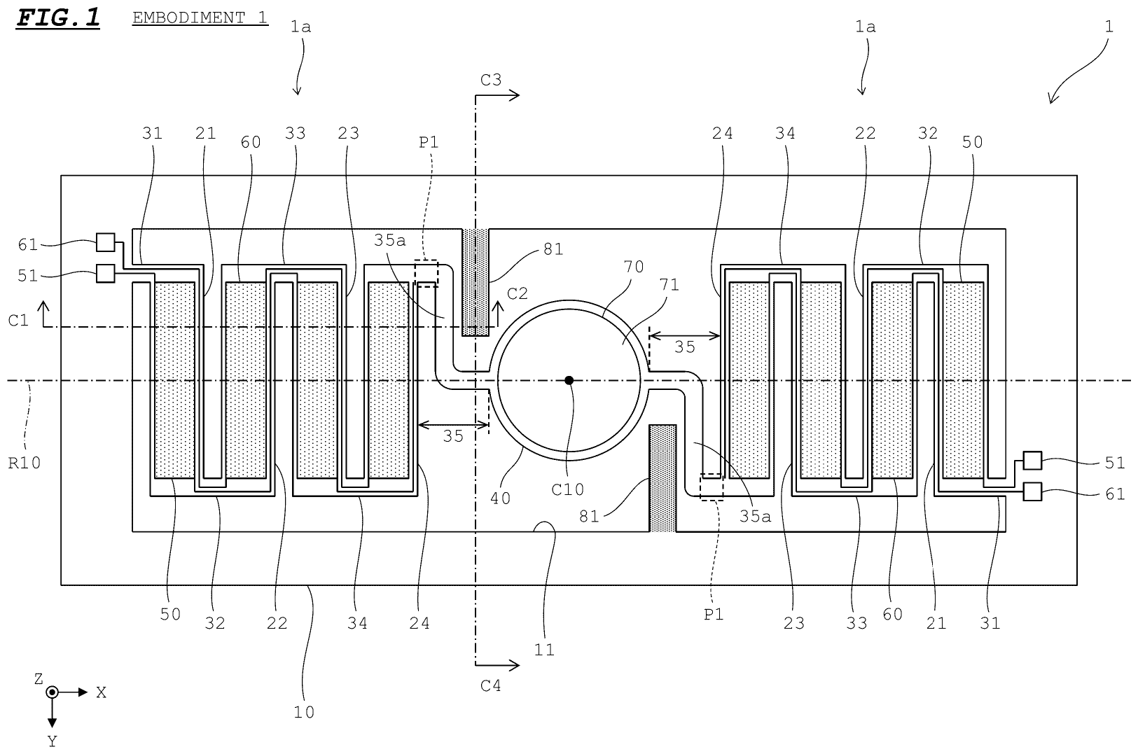

FIG. 1 is a plan view schematically showing a configuration of an optical reflective element 1.

The optical reflective element 1 includes a fixation part 10, a pair of sets of vibration plates 21 to 24, a pair of sets of connection parts 31 to 34, a pair of coupling beams 35, a movable part 40, a pair of drive parts 50, a pair of drive parts 60, a mirror 70, and a pair of stoppers 81. The optical reflective element 1 is configured to be symmetrical in the X-axis direction and the Y-axis direction about a center C10.

The fixation part 10 is a so-called frame body having a frame shape. Each part of the optical reflective element 1 other than the fixation part 10 is placed in an opening 11 which penetrates the fixation part 10 in the Z-axis direction at the center of the fixation part 10.

The meander-type vibration plates 21 to 24, the connection parts 31 to 34, and the coupling beam 35 are placed between the movable part 40 and each of the side on the X-axis negative side of the fixation part 10 and the side on the X-axis positive side of the fixation part 10. That is, the pair of sets of vibration plates 21 to 24, the pair of sets of connection parts 31 to 34, and the pair of coupling beams 35 are placed with the movable part 40 interposed therebetween. The vibration plates 21 to 24 and the connection parts 31 to 34 located on each of the X-axis negative side and the X-axis positive side of the movable part 40 form a meander structure 1a. The meander structure 1a and the coupling beam 35 on the X-axis negative side and the meander structure 1a and the coupling beam 35 on the X-axis positive side are point-symmetrical about the center C10.

The movable part 40 has a circular shape in a plan view. The movable part 40 is supported by the fixation part 10 via the meander structure 1a and the coupling beam 35 on each of the X-axis negative side and the X-axis positive side. The movable part 40 is placed at the position of the center C10, and rotates about a rotation axis R10 which passes through the center C10 and extends in the X-axis direction. The movable part 40 has a symmetrical shape about the rotation axis R10 in a plan view.

The vibration plates 21 to 24 each have a rectangular shape that is longer in the Y-axis direction than in the X-axis direction. The vibration plates 21 to 24 on the X-axis negative side of the movable part 40 and the vibration plates 21 to 24 on the X-axis positive side of the movable part 40 are point-symmetrical about the center C10, and thus, for convenience, the vibration plates 21 to 24 on the X-axis negative side of the movable part 40 will be described here. The vibration plate 21 is connected at an end portion thereof on the Y-axis negative side to the fixation part 10 by the connection part 31. The vibration plate 22 is connected at an end portion thereof on the Y-axis positive side to the vibration plate 21 by a connection part 32. The vibration plate 23 is connected at an end portion thereof on the Y-axis negative side to the vibration plate 22 by the connection part 33. The vibration plate 24 is connected at an end portion thereof on the Y-axis positive side to the vibration plate 23 by the connection part 34. The vibration plate 24 is connected at an end portion thereof on the Y-axis negative side to the movable part 40 by the coupling beam 35.

Each coupling beam 35 couples the vibration plate 24 to the movable part 40. The coupling beam 35 has a portion 35a parallel to a direction (Y-axis direction) perpendicular to the rotation axis R10. On the X-axis negative side of the movable part 40, end portions on the Y-axis negative side and the Y-axis positive side of the portion 35a are connected to the vibration plate 24 and the movable part 40, respectively, by portions of the coupling beam 35 that extend in the X-axis direction. On the X-axis positive side of the movable part 40, end portions on the Y-axis positive side and the Y-axis negative side of the portion 35a are connected to the vibration plate 24 and the movable part 40, respectively, by portions of the coupling beam 35 that extend in the X-axis direction.

On the X-axis negative side of the movable part 40, the drive part 50 and the drive part 60 are placed on the upper surfaces of the vibration plates 21 to 24, the connection parts 31 to 34, and the fixation part 10. Similarly, on the X-axis positive side of the movable part 40, the drive part 50 and the drive part 60 are placed on the upper surfaces of the vibration plates 21 to 24, the connection parts 31 to 34, and the fixation part 10. In FIG. 1, for convenience, the drive parts 50 and 60 are shown by thin hatching.

The drive parts 50 and 60 rotate the movable part 40 about the rotation axis R10. The drive part 50 is a so-called piezoelectric transducer. A piezoelectric transducer is sometimes called piezoelectric actuator. On the X-axis negative side of the movable part 40, the drive parts 50 and 60 are connected to electrodes 51 and 61 placed on the fixation part 10, respectively. Similarly, on the X-axis positive side of the movable part 40, the drive parts 50 and 60 are connected to electrodes 51 and 61 placed on the fixation part 10, respectively.

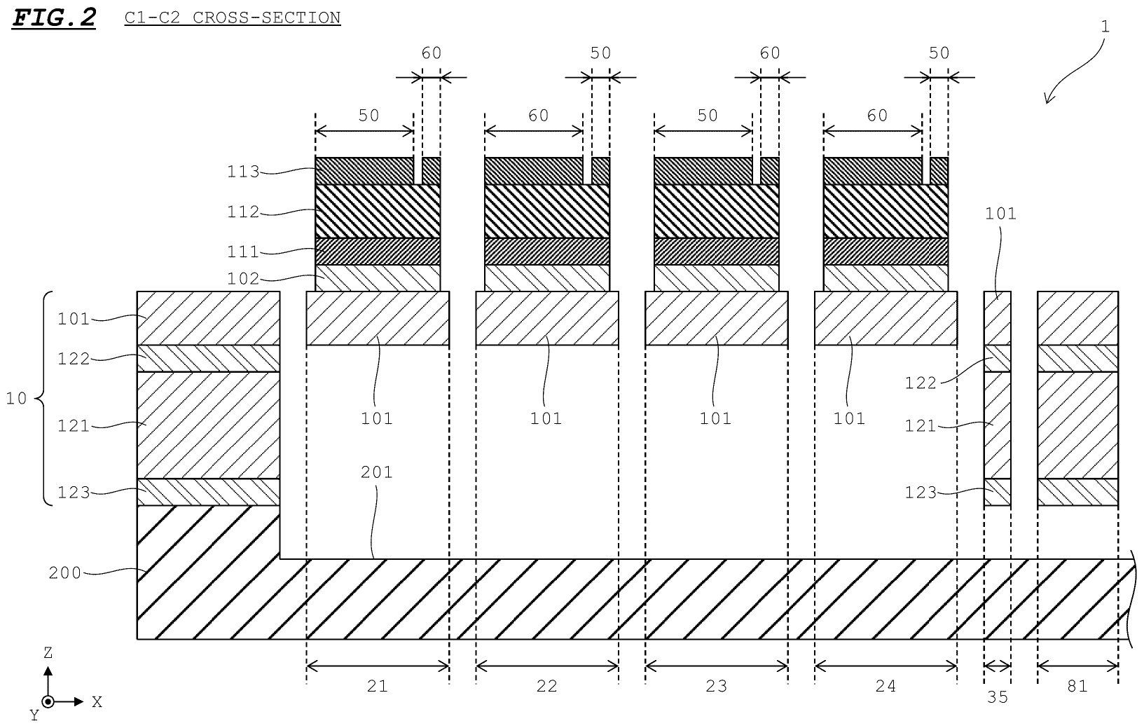

The drive parts 50 and 60 each include a lower electrode 111, a piezoelectric layer 112, and an upper electrode 113, as described later with reference to FIG. 2. At the position of the electrode 51, an external voltage supply part is connected to the lower electrode 111 and the upper electrode 113 of the drive part 50, and at the position of the electrode 61, an external voltage supply part is connected to the lower electrode 111 and the upper electrode 113 of the drive part 60. For example, the lower electrode 111 is connected to a ground, and a voltage is applied to the upper electrode 113. Accordingly, a voltage is applied to the piezoelectric layer 112 interposed between the lower electrode 111 and the upper electrode 113, and the piezoelectric layer 112 becomes deformed.

The drive part 50 connected to the electrode 51 is wider in the X-axis direction on the vibration plates 21 and 23 and narrower in the X-axis direction on the vibration plates 22 and 24. The drive part 60 connected to the electrode 61 is wider in the X-axis direction on the vibration plates 22 and 24 and narrower in the X-axis direction on the vibration plates 21 and 23. Therefore, the drive part 50 connected to the electrode 51 mainly vibrates the vibration plates 21 and 23 and functions as a wiring part on the vibration plates 22 and 24. Meanwhile, the drive part 60 connected to the electrode 61 mainly vibrates the vibration plates 22 and 24 and functions as a wiring part on the vibration plates 21 and 23.

When the optical reflective element 1 is driven, a drive signal (voltage) is applied to the drive part 50 via the electrode 51, and a drive signal (voltage) is applied to the drive part 60 via the electrode 61. When the drive signal is applied to the drive part 50, the piezoelectric layer 112 within the drive part 50 becomes deformed, and the vibration plates 21 and 23 vibrate so as to bend. When the drive signal is applied to the drive part 60, the piezoelectric layer 112 within the drive part 60 becomes deformed, and the vibration plates 22 and 24 vibrate so as to bend.

At this time, on the X-axis negative side of the movable part 40, drive signals having phases different from each other by 180° are applied to the drive part 50 and the drive part 60, and, on the X-axis positive side of the movable part 40, drive signals having phases different from each other by 180° are applied to the drive part 50 and the drive part 60. In addition, drive signals having phases different from each other by 180° are applied to the drive part 50 on the X-axis negative side of the movable part 40 and the drive part 50 on the X-axis positive side of the movable part 40, and drive signals having phases different from each other by 180° are applied to the drive part 60 on the X-axis negative side of the movable part 40 and the drive part 60 on the X-axis positive side of the movable part 40. Accordingly, the movable part 40 and the mirror 70 rotate about the rotation axis R10.

The mirror 70 is composed of a dielectric multilayer film, a metal film, or the like that reflects light, and a reflection surface 71 is formed on the upper surface (surface on the Z-axis positive side) of the mirror 70.

The pair of stoppers 81 are placed on the X-axis negative side and the X-axis positive side of the movable part 40, respectively. The stopper 81 on the X-axis negative side of the movable part 40 extends in the Y-axis positive direction from the side on the Y-axis negative side of the fixation part 10. The stopper 81 on the X-axis positive side of the movable part 40 extends in the Y-axis negative direction from the side on the Y-axis positive side of the fixation part 10. The stopper 81 on the X-axis negative side of the movable part 40 is adjacent to a coupling position P1 between the vibration plate 24 and the coupling beam 35 in the X-axis positive direction. The stopper 81 on the X-axis positive side of the movable part 40 is adjacent to a coupling position P1 between the vibration plate 24 and the coupling beam 35 in the X-axis negative direction. Here, “adjacent” means a state where, in a normal state, the stopper 81 is not in contact with a target member, but is aligned with the target member so as to be adjacent to the target member in a plan view with a predetermined gap from the target member.

Each stopper 81 has a rectangular shape in a plan view, and a distal end of the stopper 81 in a plan view is closer to the center C10 in the Y-axis direction than the coupling position P1. Specifically, in the Y-axis direction, the distal end of the stopper 81 is positioned in the vicinity of the midpoint of the portion 35a of the coupling beam 35.

FIG. 2 is a side view schematically showing a C1-C2 cross-section of FIG. 1.

The vibration plates 21 to 24 are each composed of a device layer 101. The device layer 101 is made of Si. The fixation part 10 is composed of a device layer 101, a base layer 121, and thermal oxide films 122 and 123. The base layer 121 is made of Si, and the thermal oxide films 122 and 123 are made of SiO₂.

Similar to the fixation part 10, the coupling beam 35 and the stopper 81 are each composed of a device layer 101, a base layer 121, and thermal oxide films 122 and 123.

Similar to the fixation part 10, the connection parts 31 to 34 are each composed of a device layer 101, a base layer 121, and thermal oxide films 122 and 123. The movable part 40 is composed of a device layer 101, and a rib composed of a base layer 121 and thermal oxide films 122 and 123 is formed on the lower surface (surface on the Z-axis negative side) in the vicinity of the outer periphery of the movable part 40.

The fixation part 10, the vibration plates 21 to 24, the connection parts 31 to 34, the coupling beam 35, the movable part 40, and the stopper 81 all include the common device layer 101. That is, the device layer 101 included in each part described above is integrally formed by a common Si substrate.

The fixation part 10, the connection parts 31 to 34, the coupling beam 35, the rib on the lower surface of the movable part 40, and the stopper 81 are formed by processing an SOI substrate having SiO₂ inserted between an Si substrate and Si at a surface layer. Below the base layer 121, a masking process is performed on a region corresponding to each part described above, and regions where each part described above is not to be formed are removed by etching. Then, each part described above is formed by removing a masking member. In each part described above, the base layer 121 and the thermal oxide films 122 and 123 are formed on the lower surface of the device layer 101, whereby the mechanical strength of each part can be increased.

A thermal oxide film 102 is formed on the upper surfaces of the device layers 101 of the vibration plates 21 to 24. The thermal oxide film 102 is made of SiO₂.

The drive parts 50 and 60 are each composed of the lower electrode 111, a piezoelectric layer 112, and the upper electrode 113. The lower electrode 111 is formed on the upper surface of the thermal oxide film 102, the piezoelectric layer 112 is formed on the upper surface of the lower electrode 111, and the upper electrode 113 is formed on the upper surface of the piezoelectric layer 112. The thermal oxide film 102, the lower electrode 111, and the piezoelectric layer 112 are formed over the entire ranges in the X-axis direction of the vibration plates 21 to 24, and the upper electrode 113 is formed only in ranges corresponding to the drive parts 50 and 60. The lower electrode 111 is made of, for example, platinum (Pt). The piezoelectric layer 112 is made of, for example, PZT (lead zirconate titanate: Pb(Zr, Ti)O₃). The upper electrode 113 is made of, for example, gold (Au).

The completed optical reflective element 1 is installed on a structure 200. A recess 201 is formed at the center of the upper surface of the structure 200. In a plan view, the shape of the recess 201 coincides with the shape of the opening 11 (see FIG. 1) of the fixation part 10. By providing the recess 201, a space for displacement of the vibration plates 21 to 24, the connection parts 31 to 34, the coupling beam 35, and the movable part 40 in the Z-axis direction during the rotational movement of the movable part 40 is ensured.

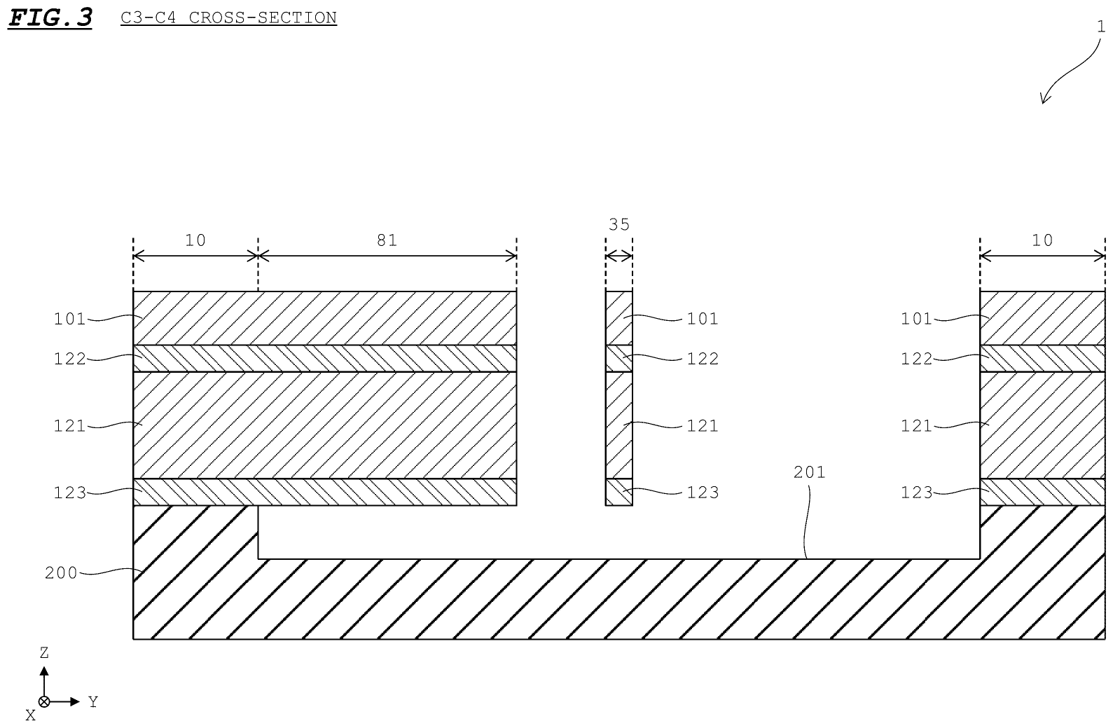

FIG. 3 is a side view schematically showing a C3-C4 cross-section of FIG. 1.

As described with reference to FIG. 2, the fixation part 10, the coupling beam 35, and the stopper 81 are each composed of the device layer 101, the base layer 121, and the thermal oxide films 122 and 123. The stopper 81 is a part of the fixation part 10 that protrudes from the side on the Y-axis negative side of the fixation part 10 toward the Y-axis positive side. That is, the fixation part 10 and the stopper 81 are integrally formed.

Meanwhile, in an optical reflective element in which a movable part is supported by meander-shaped vibration plates, when an impact is applied in the X-axis direction, the movable part having a large mass is mainly displaced in the direction of the impact. At this time, the meander-shaped vibration plates are pulled by the movable part and displaced in the X-axis direction. In addition, during the displacement in the X-axis direction, the meander-shaped vibration plates are also displaced in the Z-axis direction. Thus, when an impact is applied in the X-axis direction, the meander-shaped vibration plates are displaced in the X-axis direction and the Z-axis direction, whereby stress may be concentrated on a connection part connecting the vibration plates to each other and the vicinity of the connection part may be damaged.

In contrast, in Embodiment 1, the pair of stoppers 81 are placed adjacent to the pair of coupling beams 35. Accordingly, when an impact is applied in the X-axis direction, the movable part 40 and each coupling beam 35 are restricted to be displaced in the X-axis direction, so that a force in the X-axis direction based on the masses of the movable part 40 and the coupling beam 35 is inhibited from being applied to the meander structure 1a (see FIG. 1) composed of the vibration plates 21 to 24 and the connection parts 31 to 34. Therefore, displacement of the meander structure 1a in the X-axis direction by an impact in the X-axis direction is suppressed. In addition, since displacement of the meander structure 1a in the X-axis direction is suppressed, displacement of the vibration plates 21 to 24 in the Z-axis direction is also suppressed. Thus, concentration of stress generated in accordance with an impact in the X-axis direction can be effectively suppressed.

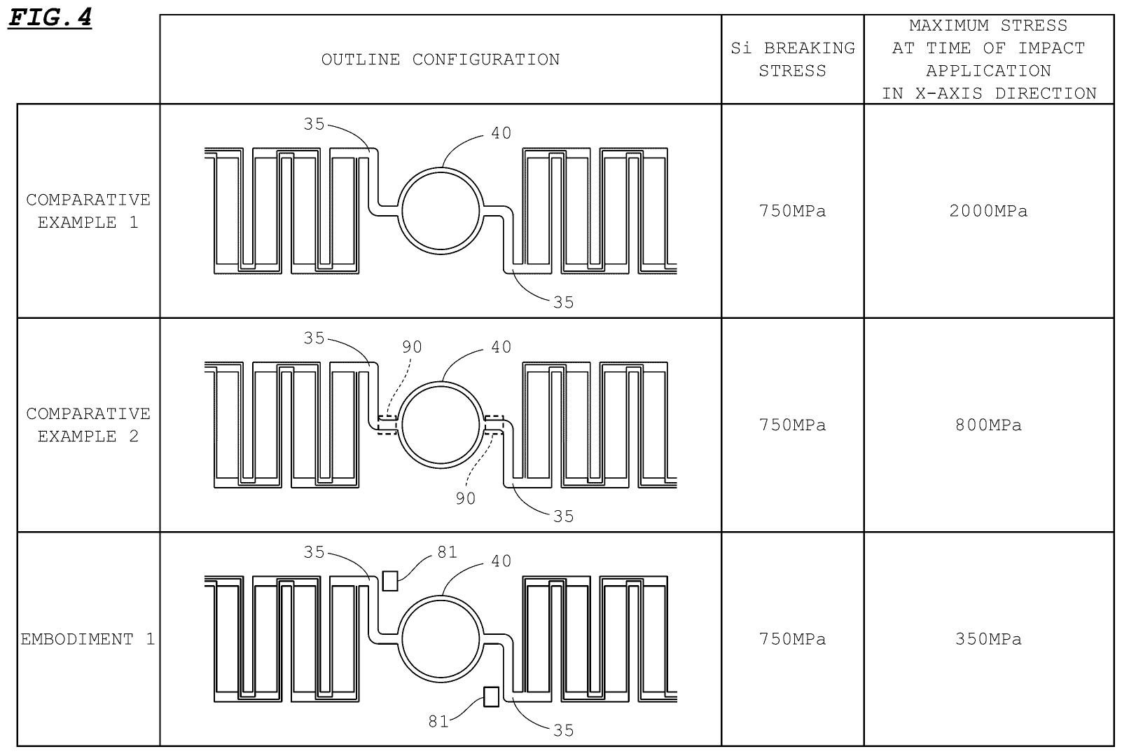

FIG. 4 shows simulation results of maximum stress when an impact is applied in the X-axis direction, according to Comparative Examples 1 and 2 and Embodiment 1.

The inventors obtained maximum stress generated in an optical reflective element when an impact was applied to the optical reflective element in the X-axis direction in each configuration of Comparative Examples 1 and 2 and Embodiment 1 by simulation.

In Comparative Examples 1 and 2 and Embodiment 1 of this simulation, the meander structure 1a (the vibration plates 21 to 24 and the connection parts 31 to 34), the coupling beam 35, the movable part 40, and the mirror 70 shown in FIG. 1 have the same configuration. In Comparative Example 1, no stopper is placed. In Comparative Example 2, stoppers 90 are placed on the Z-axis positive side and the Z-axis negative side of end portions on the movable part 40 side of the coupling beams 35, respectively. In Embodiment 1, as shown in FIG. 1, the stoppers 81 are placed adjacent to the coupling positions P1 between the vibration plates 24 and the coupling beams 35 in the X-axis direction. In each configuration of Comparative Examples 1 and 2 and Embodiment 1, the stress (Si breaking stress) when the device layer 101 (see FIG. 2) made of Si is broken is 750 MPa.

According to the simulation results shown in FIG. 4, in the case of Comparative Example 1, the maximum stress at the time of impact application in the X-axis direction is 2000 MPa, which is much higher than the Si breaking stress. Therefore, in the case where no stopper is provided as in Comparative Example 1, when an impact is applied in the X-axis direction, the vibration plates 21 to 24 near the connection parts 31 to 34 may be damaged.

In the case of Comparative Example 2, the maximum stress at the time of impact application in the X-axis direction is 800 MPa, which is slightly higher than the Si breaking stress. In the case of Comparative Example 2, since no stoppers that suppress displacement of the coupling beams 35 in the X-axis direction are provided, each coupling beam 35 is displaced in the X-axis direction so as to follow the movable part 40 having a large mass. Therefore, displacement of each coupling beam 35 in the Z-axis direction is suppressed by the stopper 90, but the maximum stress slightly exceeds the Si breaking stress, so that the vibration plates 21 to 24 near the connection parts 31 to 34 may be damaged.

In the case of Embodiment 1, the maximum stress at the time of impact application in the X-axis direction is 350 MPa, which is much lower than the Si breaking stress. In the case of Embodiment 1, each stopper 81 inhibits the coupling beam 35 from being displaced in the X-axis direction so as to follow the movable part 40 having a large mass. Accordingly, the vibration plates 21 to 24 and the connection parts 31 to 34 which are located outward of the coupling beam 35 are also inhibited from being displaced in the X-axis direction. In addition, since the coupling beam 35 is inhibited from being displaced in the X-axis direction, a trigger itself that displaces the vibration plates 21 to 24 and the connection parts 31 to 34 does not occur, and the vibration plates 21 to 24 and the connection parts 31 to 34 are also inhibited from being displaced in the Z-axis direction. Therefore, in Embodiment 1, the maximum stress is much lower than the Si breaking stress, so that damage to the vibration plates 21 to 24 near the connection parts 31 to 34 is avoided.

### Effects of Embodiment 1

According to Embodiment 1, the following effects are achieved.

Each stopper 81 is placed adjacent to the coupling beam 35 in a direction (X-axis direction) parallel to the rotation axis R10. Accordingly, when an impact is applied to the optical reflective element 1 in the direction (X-axis direction) parallel to the rotation axis R10, displacement of the vibration plates 21 to 24 is restricted by the stopper 81. Therefore, damage to a portion (e.g., the vicinities of the connection parts 31 to 34) where stress is likely to be concentrated by displacement of the vibration plates 21 to 24 can be suppressed. Thus, the impact resistance of the optical reflective element 1 in the direction (X-axis direction) parallel to the rotation axis R10 of the movable part 40 can be improved.

In displacement of the vibration plates 21 to 24 and the connection parts 31 to 34 in the X-axis direction, the influence of the movable part 40 having a large mass is dominant. In contrast, when each stopper 81 is placed adjacent to the coupling beam 35 in the X-axis direction as described above, even if the movable part 40 attempts to be displaced in the X-axis direction, the force is not transmitted from the movable part 40 to the coupling beam 35, and the coupling beam 35 is inhibited from being displaced so as to follow the movable part 40. Therefore, displacement of the vibration plates 21 to 24 and the connection parts 31 to 34 in the X-axis direction is effectively suppressed.

In order to prevent displacement of the movable part 40 having a large mass from being transmitted to the meander structure 1a, a configuration in which a stopper is placed along the outer periphery of the movable part 40 so as to surround the movable part 40 in the X-Y plane is also conceivable. However, in this configuration, a part of light incident on the mirror 70 which is formed in the movable part 40 leaks to the outside of the movable part 40, and this light is reflected by the stopper placed along the outer periphery of the movable part 40 and becomes a cause of stray light. In addition, if a certain distance is provided between the movable part 40 and the stopper placed along the outer periphery of the movable part 40 in order to suppress such stray light, it becomes difficult to suppress displacement of the movable part 40. Therefore, it is preferable that the stopper is not placed adjacent to the movable part 40 so as to directly restrict displacement of the movable part 40, but is placed at a position separated from the movable part 40 by a certain distance (e.g., a position adjacent to the coupling position P1 as described above) to indirectly restrict displacement of the movable part 40.

Each stopper 81 is adjacent to the coupling position P1 between the vibration plate 24 and the coupling beam 35 in the direction (X-axis direction) parallel to the rotation axis R10. With this configuration, displacement of the movable part 40 in the X-axis direction in response to application of an impact in the X-axis direction can be effectively inhibited from being transmitted to the vibration plate 24.

Each coupling beam 35 has higher rigidity than the vibration plate 24, and each stopper 81 is adjacent to the coupling beam 35 in the direction (X-axis direction) parallel to the rotation axis R10. As shown in FIG. 2, whereas the vibration plate 24 is composed of only the device layer 101, the coupling beam 35 is composed of the device layer 101, the base layer 121, and the thermal oxide films 122 and 123. Therefore, the coupling beam 35 has higher rigidity than the vibration plate 24. With this configuration, since the rigidity of the coupling beam 35 is higher than the rigidity of the vibration plate 24, displacement of the coupling position P1 in the X-axis direction is suppressed by the stopper 81 which is placed adjacent to the coupling beam 35 in the X-axis direction. Therefore, displacement of the movable part 40 in the X-axis direction in response to application of an impact in the X-axis direction can be inhibited from being transmitted to the vibration plate 24.

Each coupling beam 35 has the portion 35a extending in a direction intersecting the rotation axis R10, and each stopper 81 is adjacent to the portion 35a of the coupling beam 35 in the direction (X-axis direction) parallel to the rotation axis R10. With this configuration, the stopper 81 which is placed adjacent to the portion 35a of the coupling beam 35 in the X-axis direction can suppress displacement of the portion 35a of the coupling beam 35 in the X-axis direction, thereby suppressing displacement of the coupling position P1 in the X-axis direction.

The portion 35a of the coupling beam 35 extends in the direction (Y-axis direction) perpendicularly intersecting the rotation axis R10. With this configuration, displacement of the portion 35a of the coupling beam 35 in the X-axis direction can be reliably suppressed by the stopper 81.

Each stopper 81 extends from the structure surrounding the optical reflective element 1 (e.g., the side on the Y-axis direction side of the fixation part 10). With this configuration, the stopper 81 can be placed at a stable position.

Each stopper 81 extends from the fixation part 10 surrounding the optical reflective element 1. With this configuration, the stopper 81 and each part of the optical reflective element 1 can be formed simultaneously in the manufacturing process.

The pair of sets of vibration plates 21 to 24, the pair of coupling beams 35, and the pair of stoppers 81 are placed with the movable part 40 interposed therebetween, and the drive parts 50 and 60 are placed on the pair of sets of vibration plates 21 to 24. With this configuration, the rotation angle of the movable part 40 can be larger than in the case where the vibration plates 21 to 24 and the coupling beam 35 are placed only on one side in the X-axis direction with respect to the movable part 40. In addition, the movable part 40 can be held stably.

### Modification 1 of Embodiment 1

In Embodiment 1, the distal end of each stopper 81 is located in the vicinity of the midpoint in the Y-axis direction of the portion 35a of the coupling beam 35, but each stopper 81 only needs to be located so as to include the coupling position P1.

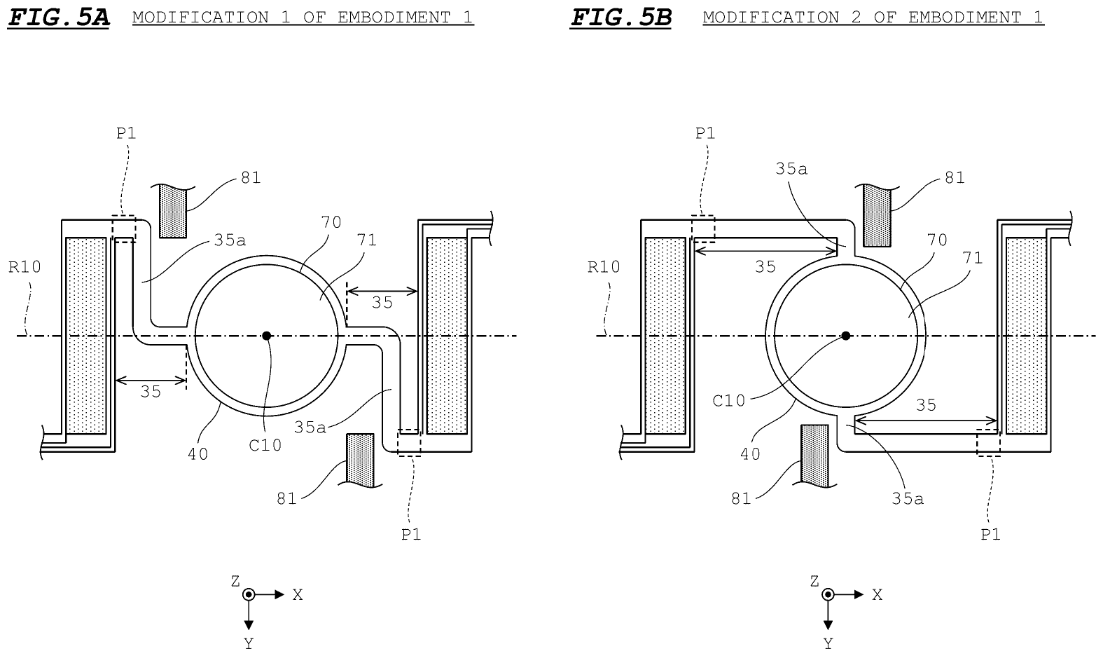

FIG. 5A is a plan view schematically showing a configuration of an optical reflective element 1 according to Modification 1 of Embodiment 1. In FIG. 5A, for convenience, only the vicinity of the movable part 40 is shown.

In Modification 1, compared to Embodiment 1, the distal end of each stopper 81 is located at the coupling position P1. The other configuration is the same as in Embodiment 1.

In Modification 1 as well, each stopper 81 is adjacent to the coupling position P1 between the vibration plate 24 and the coupling beam 35 in the direction (X-axis direction) parallel to the rotation axis R10. With this configuration, displacement of the movable part 40 in the X-axis direction in response to application of an impact in the X-axis direction can be effectively inhibited from being transmitted to the vibration plate 24. In addition, in Modification 1, the length of the stopper 81 can be minimized.

### Modification 2 of Embodiment 1

In Embodiment 1, each coupling beam 35 is connected to the end portion in the X-axis direction of the movable part 40, but may be connected to another position on the movable part 40.

FIG. 5B is a plan view schematically showing a configuration of an optical reflective element 1 according to Modification 2 of Embodiment 1. In FIG. 5B, for convenience, only the vicinity of the movable part 40 is shown

In Modification 2, compared to Embodiment 1, the portion 35a, of each coupling beam 35, extending in the Y-axis direction is directly connected to an end portion in the Y-axis direction of the movable part 40, and another end of the portion 35a is connected to the vibration plate 24 by a portion of the coupling beam 35 that extends in the X-axis direction.

In Modification 2, each stopper 81 is located adjacent to the coupling beam 35 in the direction (X-axis direction) parallel to the rotation axis R10. In this configuration as well, displacement of the vibration plates 21 to 24 is restricted by the stopper 81. Therefore, the impact resistance of the optical reflective element 1 in the direction (X-axis direction) parallel to the rotation axis R10 of the movable part 40 can be improved.

### Modification 3 of Embodiment 1

In Embodiment 1, the portion 35a of each coupling beam 35 extends in the Y-axis direction, and the other portions of the coupling beam 35 extend in the X-axis direction, but the shape of each coupling beam 35 may be another shape.

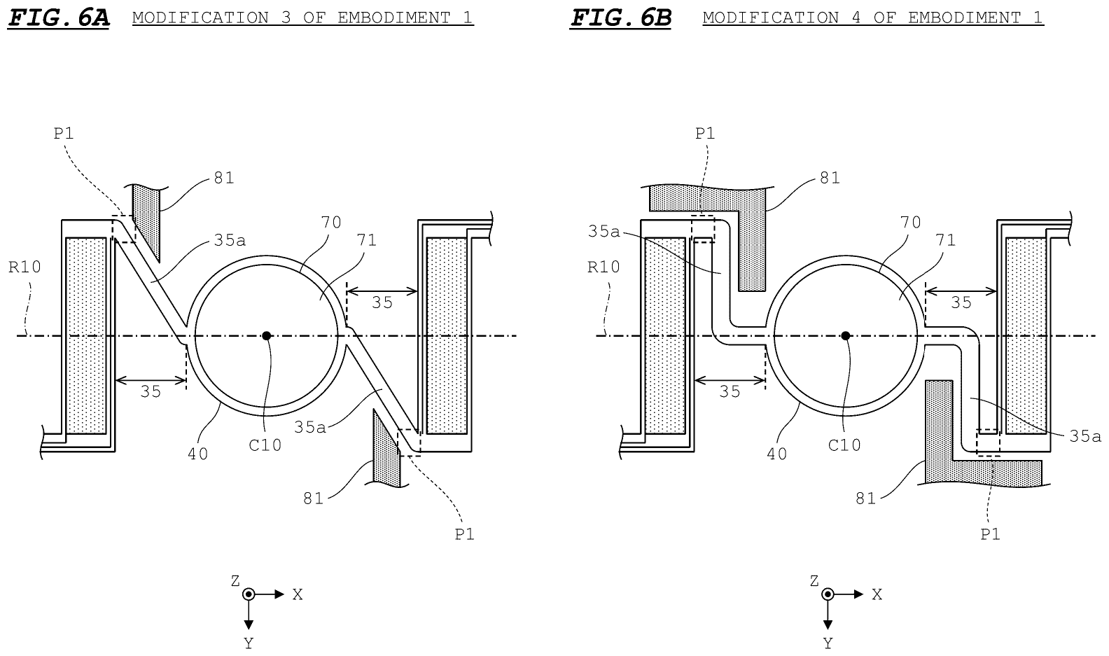

FIG. 6A is a plan view schematically showing a configuration of an optical reflective element 1 according to Modification 3 of Embodiment 1. In FIG. 6A, for convenience, only the vicinity of the movable part 40 is shown.

In Modification 3, compared to Embodiment 1, each coupling beam 35 is composed of only a portion 35a extending in an oblique direction. In this case, each stopper 81 is placed adjacent to the portion 35a, which extends in the oblique direction, in the X-axis direction.

In Modification 3, each coupling beam 35 has the portion 35a extending in a direction intersecting the rotation axis R10 (direction inclined with respect to the X-axis direction and the Y-axis direction), and each stopper 81 is adjacent to the portion 35a of the coupling beam 35 in the direction (X-axis direction) parallel to the rotation axis R10. In this configuration as well, the stopper 81 can suppress displacement in the X-axis direction of the portion 35a extending in the oblique direction, thereby suppressing displacement of the coupling position P1 in the X-axis direction. However, in order to more reliably suppress displacement of each coupling beam 35, it is preferable that each stopper 81 is placed with respect to the portion 35a, which extends in the Y-axis direction, as in Embodiment 1.

### Modification 4 of Embodiment 1

In Embodiment 1, each stopper 81 is placed adjacent to the coupling beam 35 only in the X-axis direction, but may be placed adjacent to the coupling beam 35 in the Y-axis direction, or may be placed adjacent to the vibration plates 21 to 24 in the Y-axis direction.

FIG. 6B is a plan view schematically showing a configuration of an optical reflective element 1 according to Modification 4 of Embodiment 1. In FIG. 6B, for convenience, only the vicinity of the movable part 40 is shown.

In Modification 4, compared to Embodiment 1, each stopper 81 has a shape in which the stopper 81 is also adjacent to the outer side of the coupling beam 35 and the vibration plate 24 with respect to the center C10. That is, the stopper 81 in this case includes a portion adjacent to the portion 35a in the X-axis direction, and a portion adjacent to the coupling beam 35 and the vibration plate 24 in the vicinity of the coupling position P1 in the Y-axis direction.

In Modification 4, displacement of the vibration plate 24 in the Y-axis direction can be suppressed, so that displacement of the meander structure 1a in the X-Y plane can be further suppressed.

### Modification 5 of Embodiment 1

In Embodiment 1, the pair of meander structures 1a (the vibration plates 21 to 24 and the connection parts 31), the pair of coupling beams 35, and the pair of stoppers 81 are placed so as to be point-symmetrical about the center C10, but do not necessarily have to be placed so as to be point-symmetrical.

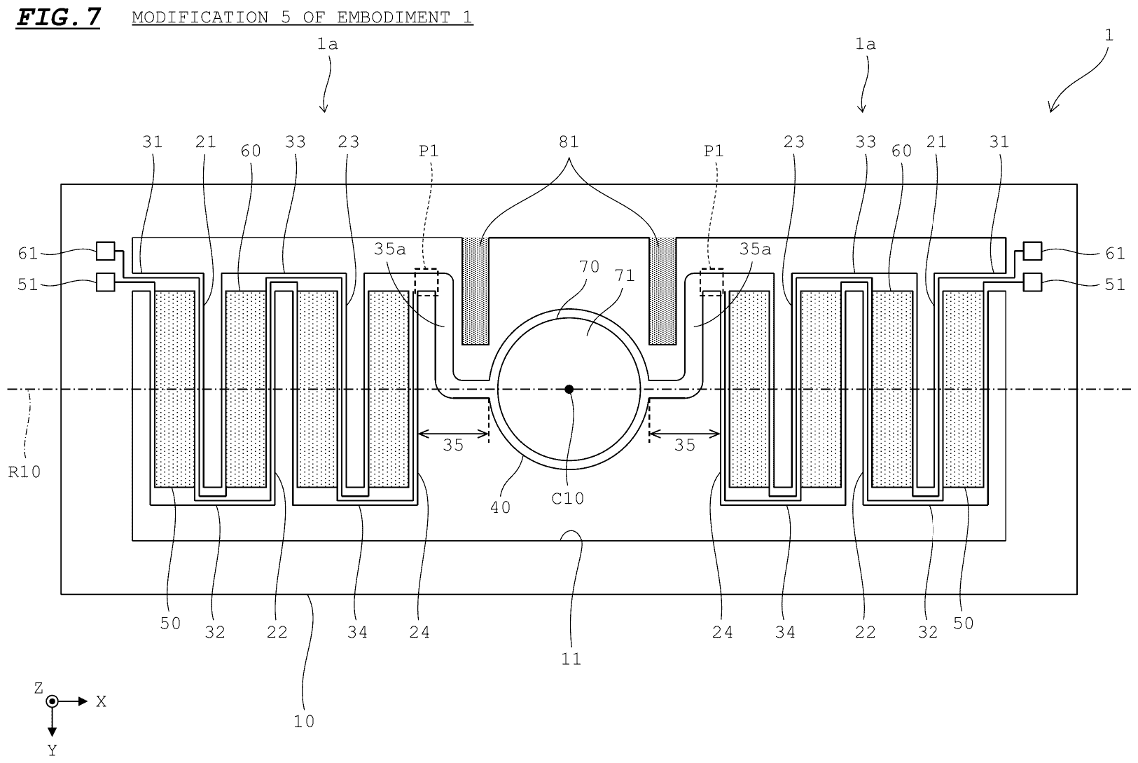

FIG. 7 is a plan view schematically showing a configuration of an optical reflective element 1 according to Modification 5 of Embodiment 1.

In Modification 5, compared to Embodiment 1, the pair of meander structures 1a, the pair of coupling beams 35, and the pair of stoppers 81 are placed so as to be line-symmetrical about a straight line that passes through the center C10 and is parallel to the Y-axis direction.

In Modification 5 as well, each stopper 81 is placed adjacent to the coupling beam 35 in the direction (X-axis direction) parallel to the rotation axis R10. Accordingly, displacement of the vibration plates 21 to 24 is restricted by the stopper 81. Therefore, the impact resistance of the optical reflective element 1 in the direction (X-axis direction) parallel to the rotation axis R10 of the movable part 40 can be improved.

### Embodiment 2

In Embodiment 2, stoppers 82 to 86 for suppressing displacement of the vibration plates 21 to 24 in the X-axis direction are further placed in addition to the stoppers 81.

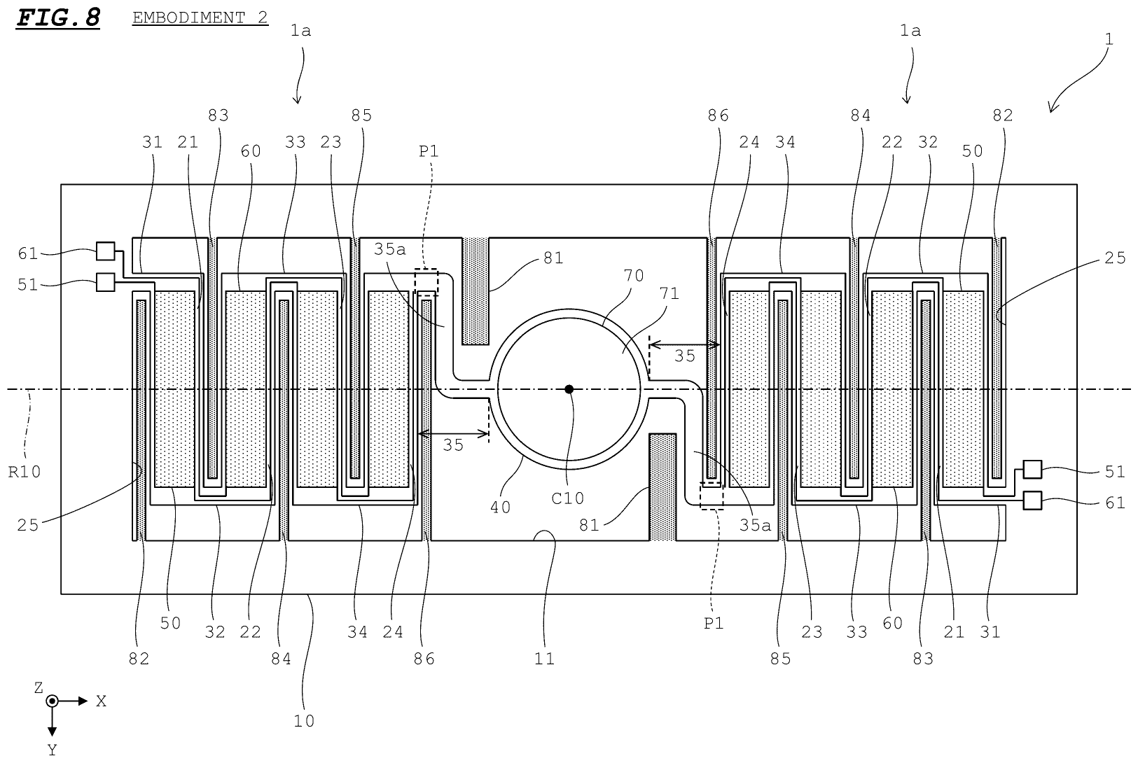

FIG. 8 is a plan view schematically showing a configuration of an optical reflective element 1 according to Embodiment 2.

In Embodiment 2, compared to Embodiment 1, a pair of sets of stoppers 82 to 86 are placed in respective gaps 25 of the meander structures 1a. Each meander structure 1a has gaps 25 between the fixation part 10 and the vibration plate 21, between the vibration plate 21 and the vibration plate 22, between the vibration plate 22 and the vibration plate 23, between the vibration plate 23 and the vibration plate 24, and between the vibration plate 24 and the coupling beam 35 in the X-axis direction.

The stopper 82 is placed in the gap 25 between the fixation part 10 and the vibration plate 21, the stopper 83 is placed in the gap 25 between the vibration plate 21 and the vibration plate 22, the stopper 84 is placed in the gap 25 between the vibration plate 22 and the vibration plate 23, the stopper 85 is placed in the gap 25 between the vibration plate 23 and the vibration plate 24, and the stopper 86 is placed in the gap 25 between the vibration plate 24 and the coupling beam 35. Similar to the stoppers 81, the stoppers 82 to 86 each extend in the Y-axis direction from the side on the Y-axis negative side or the side on the Y-axis positive side of the fixation part 10. The stoppers 82 to 86 are placed so as to include the entire ranges of the respective gaps 25.

In Embodiment 2, the stoppers 82 to 86 are placed in the five gaps 25 of each meander structure 1a in the direction (X-axis direction) parallel to the rotation axis R10, respectively. As described above, in displacement of the vibration plates 21 to 24 and the connection parts 31 to 34 in the X-axis direction, the influence of the movable part 40 having a large mass is dominant, but the vibration plates 21 to 24 and the connection parts 31 to 34 also attempt to be displaced in the X-axis direction by the masses of the vibration plates 21 to 24 and the connection parts 31 to 34 themselves. Therefore, since the stoppers 82 to 86 are placed in the respective gaps 25 of each meander structure 1a, displacement of the vibration plates 21 to 24 and the connection parts 31 to 34 themselves can be suppressed, so that damage to the portion (e.g., the vicinities of the connection parts 31 to 34) where stress is likely to be concentrated can be further suppressed.

### Modification of Embodiment 2

In Embodiment 2, the stoppers 82 to 86 are placed in the respective gaps 25 of each meander structure 1a, and the stopper 81 is placed adjacent to each coupling position P1. However, the present invention is not limited thereto, and in the case where a stopper is placed in a gap 25 of each meander structure 1a, the stopper 81 does not have to be placed at each coupling position P1.

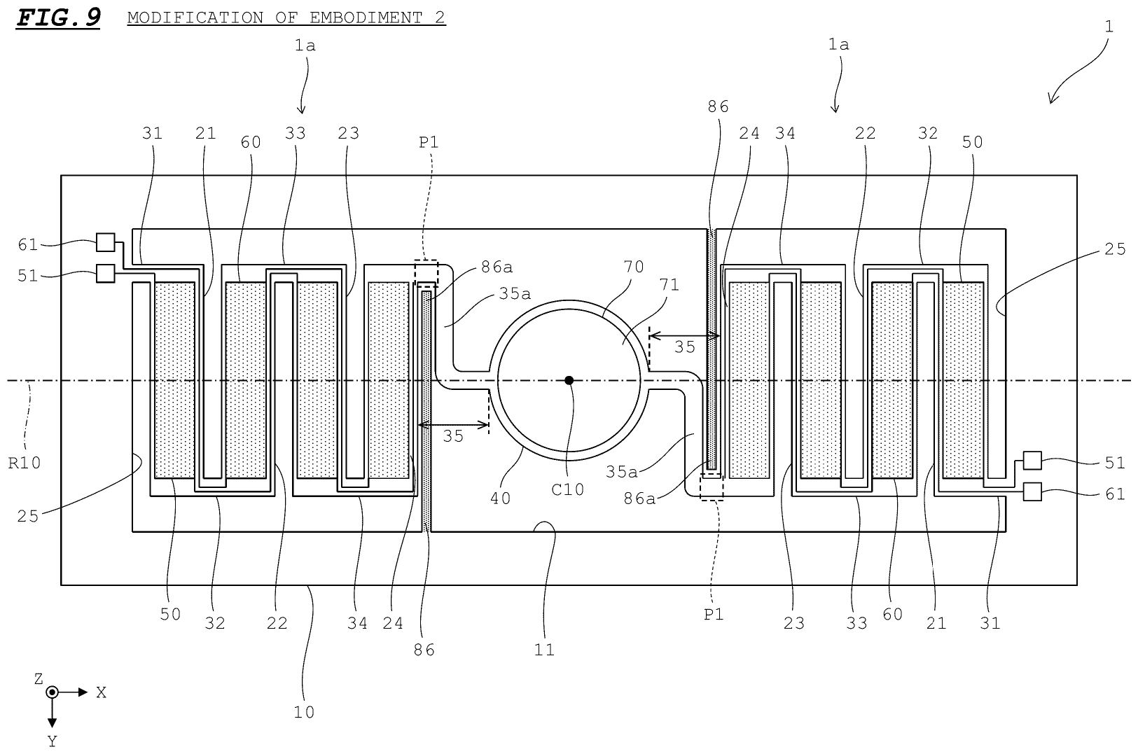

FIG. 9 is a plan view schematically showing a configuration of an optical reflective element 1 according to a modification of Embodiment 2.

In this modification, compared to Embodiment 2, the stoppers 81 to 85 are omitted. With this configuration, when an impact is applied in the X-axis direction, the movable part 40 and each coupling beam 35 are not restricted to be displaced in the X-axis direction, but since each stopper 86 is placed in the gap 25 between the coupling beam 35 and the vibration plate 24, a force in the X-axis direction based on the masses of the movable part 40 and the coupling beam 35 is inhibited from being applied to the meander structure 1a. Therefore, displacement of the meander structure 1a in the X-axis direction by an impact in the X-axis direction is suppressed. Thus, damage to the portion (e.g., the vicinities of the connection parts 31 to 34) where stress is likely to be concentrated can be suppressed.

However, when the stopper 81 is placed adjacent to each coupling position P1 in addition to each stopper 86 as shown in Embodiment 2 in FIG. 8, displacement of the vibration plates 21 to 24 and the connection parts 31 to 34 can be more reliably suppressed. Moreover, when the four stoppers 82 to 85 are placed in the other gaps 25 in addition to the stopper 86, displacement of the vibration plates 21 to 24 and the connection parts 31 to 34 can be more reliably suppressed.

In this modification, as shown in FIG. 9, a distal end 86a of each stopper 86 is positioned adjacent to the coupling position P1 in the Y-axis direction, but may be away from the coupling position P1. However, if the distal end 86a of the stopper 86 is away from the coupling position P1, a moment centered on the distal end 86a is generated, and excessive stress is concentrated on the vibration plate 24 in contact with the distal end 86a. Therefore, it is preferable that the stopper 86 is placed adjacent to the coupling position P1 in the Y-axis direction as shown in FIG. 9.

### Embodiment 3

In Embodiment 1, the stoppers 81 are formed so as to protrude in the Y-axis direction from the sides on the Y-axis negative side and the Y-axis positive side of the fixation part 10, respectively. In contrast, in Embodiment 3, stoppers 131 are formed so as to protrude upward from the structure 200 placed below the fixation part 10.

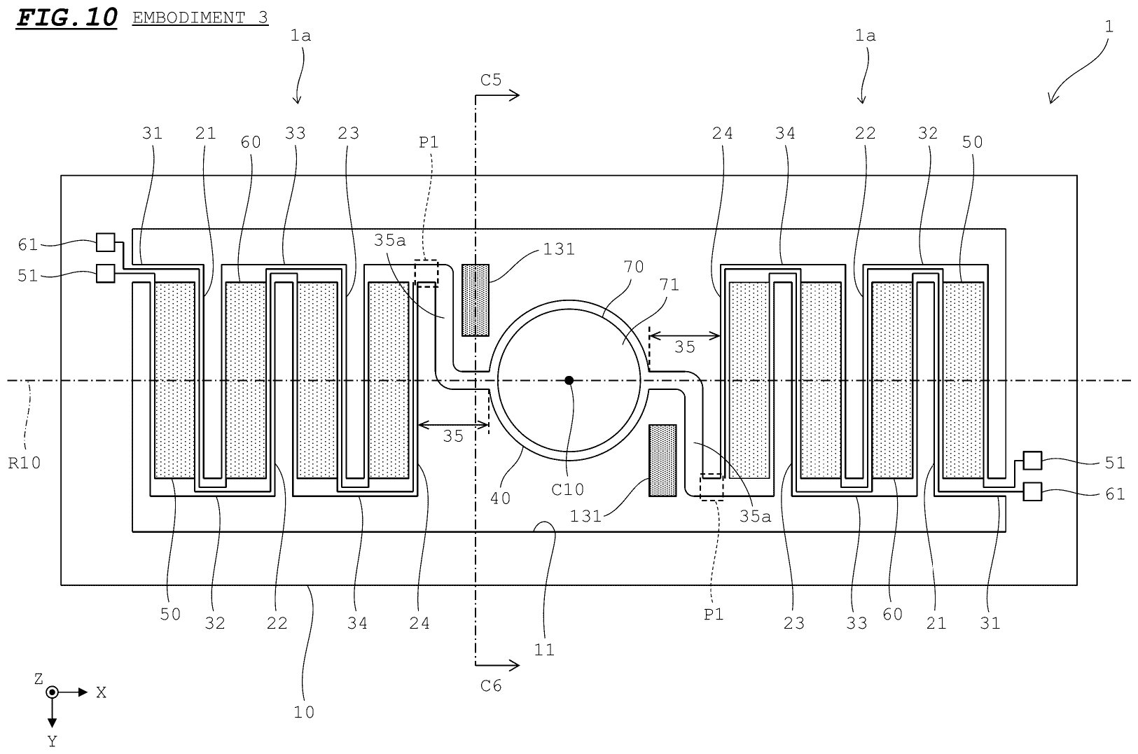

FIG. 10 is a plan view schematically showing a configuration of an optical reflective element 1 according to Embodiment 3.

In Embodiment 3, compared to Embodiment 1, a pair of stoppers 131 are placed instead of the pair of stoppers 81. Each stopper 131 is formed on the structure 200 which supports the lower surface of the fixation part 10. In Embodiment 3 as well, each stopper 131 is placed adjacent to the coupling position P1 in the X-axis direction, and the range where each stopper 131 is formed is from the coupling position P1 to the vicinity of the midpoint of the portion 35a of the coupling beam 35 in the Y-axis direction.

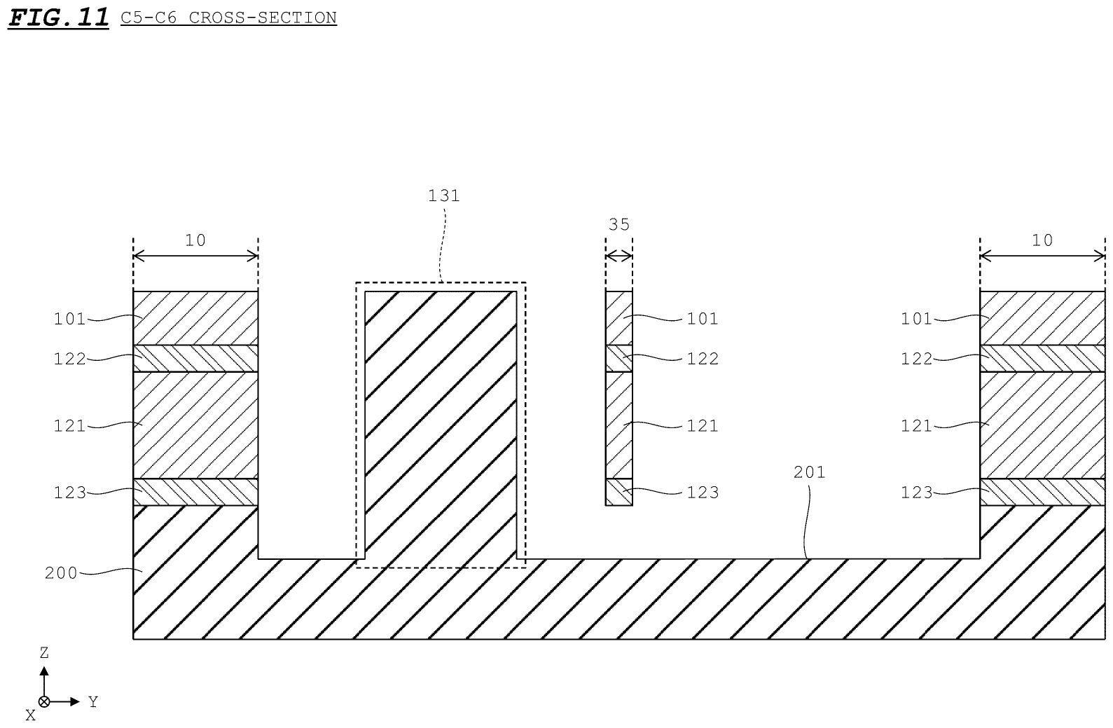

FIG. 11 is a side view schematically showing a C5-C6 cross-section of FIG. 10.

The stopper 131 is formed so as to protrude upward from the bottom surface of the recess 201 of the structure 200. The stopper 131 is made of the same material as the structure 200, and is integrally formed with the structure 200. The stopper 131 may be composed of a member separate from the structure 200, and may be installed in the recess 201 of the structure 200 by means of adhesion or the like. The stopper 131 may be made of a resin or metal, or may be made of Si and SiO₂, similar to the stopper 81 of Embodiment 1.

In Embodiment 3, as in Embodiment 1, each stopper 131 is placed adjacent to the coupling beam 35 in the direction (X-axis direction) parallel to the rotation axis R10. Accordingly, when an impact is applied to the optical reflective element 1 in the direction (X-axis direction) parallel to the rotation axis R10, displacement of the vibration plates 21 to 24 is restricted by the stopper 131. Therefore, damage to the portion (e.g., the vicinities of the connection parts 31 to 34) where stress is likely to be concentrated by displacement of the vibration plates 21 to 24 can be suppressed. Thus, the impact resistance of the optical reflective element 1 in the direction (X-axis direction) parallel to the rotation axis R10 of the movable part 40 can be improved.

Each stopper 131 extends from the structure 200 located in the Z-axis negative direction of (below) the optical reflective element 1. With this configuration, the stopper 131 can be freely placed as long as the stopper 131 and each part of the optical reflective element 1 do not interfere with each other.

The structure 200 is a member that supports the fixation part 10. With this configuration, the accuracy of the position of the stopper 131 with respect to each part of the optical reflective element 1 can be increased.

In Embodiment 3 as well, as in FIG. 5A, the distal end of each stopper 131 may be positioned at the coupling position P1 in the Y-axis direction. In the case where each coupling beam 35 is configured as in FIG. 5B, each stopper 131 is placed adjacent to the coupling beam 35 in the X-axis direction.

### Modification 1 of Embodiment 3

In Embodiment 3, the range where each stopper 131 is formed is from the coupling position P1 to the vicinity of the midpoint of the portion 35a of the coupling beam 35 in the Y-axis direction, but is not limited thereto.

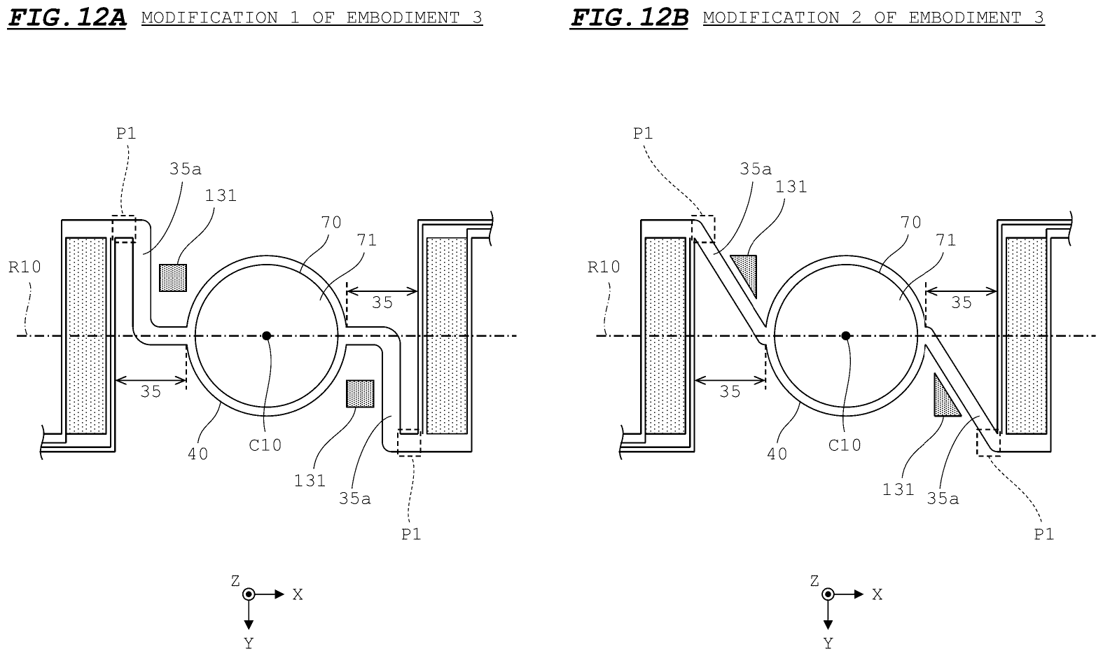

FIG. 12A is a plan view schematically showing a configuration of an optical reflective element 1 according to Modification 1 of Embodiment 3. In FIG. 12A, for convenience, only the vicinity of the movable part 40 is shown.

In Modification 1, compared to Embodiment 3, the range where each stopper 131 is formed is the vicinity of the midpoint of the portion 35a, extending in the Y-axis direction, of the coupling beam 35 in the Y-axis direction.

In Modification 1, since the rigidity of the coupling beam 35 is higher than the rigidity of the vibration plate 24, displacement of the coupling position Pl in the X-axis direction is suppressed by the stopper 131 which is placed adjacent to the coupling beam 35 in the X-axis direction at a position other than the coupling position P1. Therefore, displacement of the movable part 40 in the X-axis direction in response to application of an impact in the X-axis direction can be inhibited from being transmitted to the vibration plate 24.

### Modification 2 of Embodiment 3

In Embodiment 3, the portion 35a of each coupling beam 35 extends in the Y-axis direction, and the other portions of the coupling beam 35 extend in the X-axis direction, but the shape of each coupling beam 35 may be another shape.

FIG. 12B is a plan view schematically showing a configuration of an optical reflective element 1 according to Modification 2 of Embodiment 3. In FIG. 12B, for convenience, only the vicinity of the movable part 40 is shown.

In Modification 2, compared to Embodiment 3, each coupling beam 35 is composed of only a portion 35a extending in an oblique direction. In this case, each stopper 131 is placed adjacent to the portion 35a, which extends in the oblique direction, in the X-axis direction. In Modification 2, the range where each stopper 131 is formed is the vicinity of the midpoint of the portion 35a of the coupling beam 35 in the Y-axis direction.

In Modification 3, each coupling beam 35 has the portion 35a extending in the direction intersecting the rotation axis R10 (direction inclined with respect to the X-axis direction and the Y-axis direction), and each stopper 131 is adjacent to the portion 35a of the coupling beam 35 in the direction (X-axis direction) parallel to the rotation axis R10 at a position other than the coupling position P1. In this configuration as well, the stopper 131 can suppress displacement in the X-axis direction of the portion 35a extending in the oblique direction, thereby suppressing displacement of the coupling position P1 in the X-axis direction. However, in order to more reliably suppress displacement of each coupling beam 35, it is preferable that each stopper 131 is placed with respect to the portion 35a, which extends in the Y-axis direction, as in Embodiment 3.

### Embodiment 4

In Embodiment 4, stoppers 132 to 136 for suppressing displacement of the vibration plates 21 to 24 in the X-axis direction are further placed in addition to the stoppers 131.

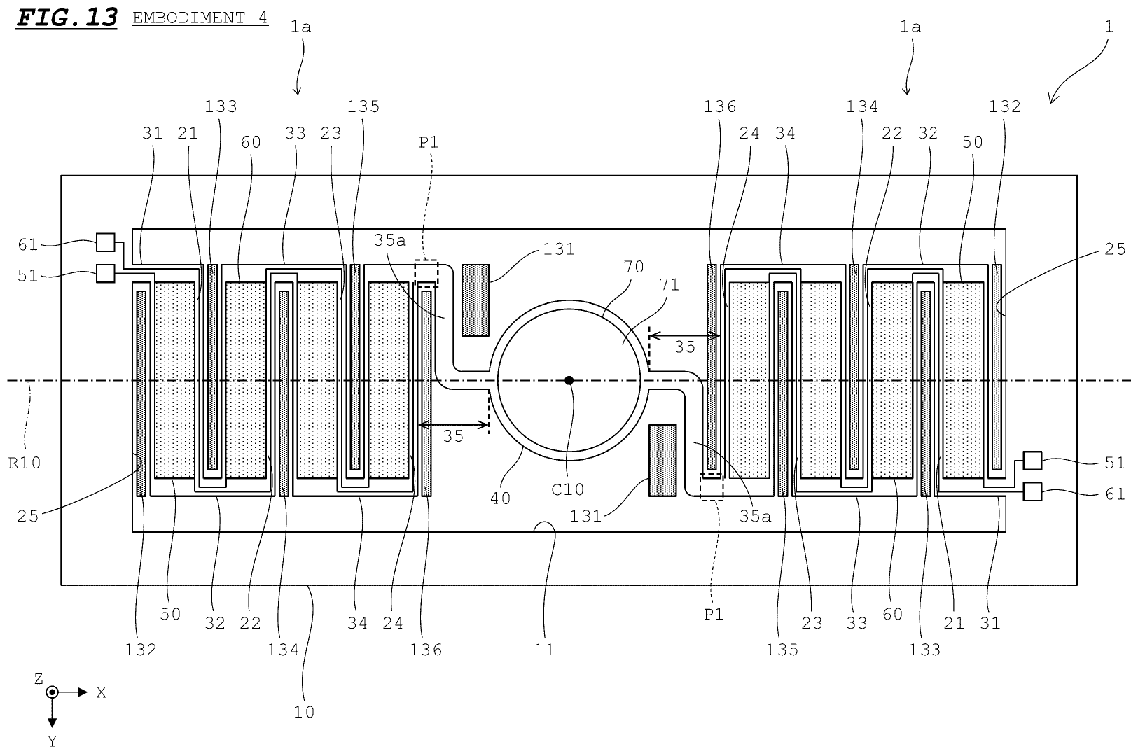

FIG. 13 is a plan view schematically showing a configuration of an optical reflective element 1 according to Embodiment 4.

In Embodiment 4, compared to Embodiment 3, a pair of sets of stoppers 132 to 136 are placed in the respective gaps 25 of the meander structures 1a. Similar to each stopper 131, the stoppers 132 to 136 are formed so as to protrude upward from the bottom surface of the recess 201 (see FIG. 11) of the structure 200. The stoppers 132 to 136 are placed in the ranges of the respective gaps 25.

In Embodiment 4, the stoppers 132 to 136 are placed in the five gaps 25 of each meander structure 1a in the direction (X-axis direction) parallel to the rotation axis R10, respectively. As described above, in displacement of the vibration plates 21 to 24 and the connection parts 31 to 34 in the X-axis direction, the influence of the movable part 40 having a large mass is dominant, but the vibration plates 21 to 24 and the connection parts 31 to 34 also attempt to be displaced in the X-axis direction by the masses of the vibration plates 21 to 24 and the connection parts 31 to 34 themselves. Therefore, since the stoppers 132 to 136 are placed in the respective gaps 25 of each meander structure 1a, displacement of the vibration plates 21 to 24 and the connection parts 31 to 34 themselves can be suppressed, so that damage to the portion (e.g., the vicinities of the connection parts 31 to 34) where stress is likely to be concentrated can be further suppressed.

### Modification of Embodiment 4

In Embodiment 4, the stoppers 132 to 136 are placed in the respective gaps 25 of each meander structure 1a, and the stopper 131 is placed adjacent to each coupling position P1. However, in the case where a stopper is placed in a gap 25 of each meander structure 1a, the stopper 131 does not have to be placed at each coupling position P1.

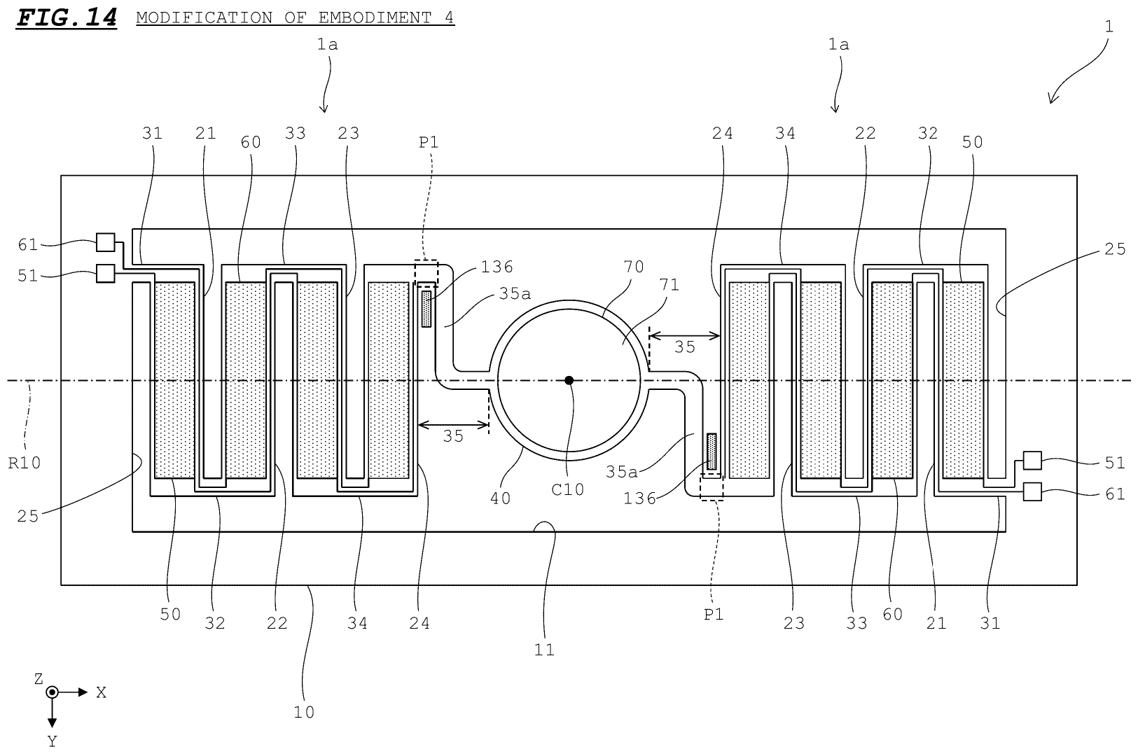

FIG. 14 is a plan view schematically showing a configuration of an optical reflective element 1 according to a modification of Embodiment 4.

In this modification, compared to Embodiment 4, the stoppers 131 to 135 are omitted. In addition, whereas each stopper 136 of Embodiment 4 is placed so as to include the entire range of the gap 25 between the vibration plate 24 and the coupling beam 35, each stopper 136 of this modification is placed in a part of the gap 25 between the vibration plate 24 and the coupling beam 35.

In this modification, when an impact is applied in the X-axis direction, the movable part 40 and each coupling beam 35 are not restricted to be displaced in the X-axis direction, but since each stopper 136 is placed in the gap 25 between the coupling beam 35 and the vibration plate 24, a force in the X-axis direction based on the masses of the movable part 40 and the coupling beam 35 is inhibited from being applied to the meander structure 1a. Therefore, displacement of the meander structure 1a in the X-axis direction by an impact in the X-axis direction is suppressed. Thus, damage to the portion (e.g., the vicinities of the connection parts 31 to 34) where stress is likely to be concentrated can be suppressed.

However, when the stopper 131 is placed adjacent to each coupling position P1 in addition to each stopper 136 as shown in Embodiment 4 in FIG. 13, displacement of the vibration plates 21 to 24 and the connection parts 31 to 34 can be more reliably suppressed. Moreover, when the four stoppers 132 to 135 are placed in the other gaps 25 in addition to the stopper 136, displacement of the vibration plates 21 to 24 and the connection parts 31 to 34 can be more reliably suppressed. Furthermore, when the stopper 136 is placed in the entire range of the gap 25 between the vibration plate 24 and the coupling beam 35, displacement of the vibration plates 21 to 24 and the connection parts 31 to 34 can be more reliably suppressed.

In this modification, as shown in FIG. 9, each stopper 136 is placed adjacent to the coupling position P1 in the Y-axis direction, but may be away from the coupling position P1. However, if the stopper 136 is away from the coupling position P1, a moment centered on the stopper 136 is generated, and excessive stress is concentrated on the vibration plate 24 in contact with the stopper 136. Therefore, it is preferable that the stopper 136 is placed adjacent to the coupling position P1 in the Y-axis direction as shown in FIGS. 13 and 14.

### Other Modifications

In Embodiments 1 to 4, each stopper has a rectangular shape in a plan view, but may have a shape including a curve. For example, in the case where each stopper is formed in an elliptical shape, at the position where the stopper and a target part (the coupling beam 35 and the vibration plates 21 to 24) are in contact with each other, damage to the target part can be suppressed compared to the case where each stopper is formed in a rectangular shape.

In Embodiment 2, the stoppers 82 to 85 are placed so as to include the entire ranges of the gaps 25, but may be placed so as to include only parts of the ranges of the gaps 25. In addition, in Embodiment 4, the stoppers 132 to 135 are placed so as to include the entire ranges of the gaps 25, but may be placed so as to include only parts of the ranges of the gaps 25. However, when each stopper is placed in a wider range of the gap 25, displacement of the vibration plates 21 to 24 in the X-axis direction can be further suppressed.

In addition to the stoppers of Embodiments 1 to 4, the stoppers 90 which restrict displacement of the coupling beams 35 in the Z-axis direction may be placed adjacent to the Z-axis negative side and the Z-axis positive side of the coupling beams 35 as in Comparative Example 2 in FIG. 4. Accordingly, when an impact is applied to the optical reflective element 1 in the Z-axis direction, displacement of each coupling beam 35 in the Z-axis direction can be suppressed.

In Embodiments 1 and 2, the stoppers 81 to 86 are formed so as to protrude in the X-Y plane from the fixation part 10, and in Embodiments 3 and 4, the stoppers 131 to 136 are formed so as to protrude in the Z-axis positive direction from the structure 200. However, the present invention is not limited thereto, and in one optical reflective element 1, stoppers formed so as to protrude in the X-Y plane from the fixation part 10 and stoppers formed so as to protrude in the Z-axis positive direction from the structure 200 may coexist.

In each of Embodiments 2 and 4, the stoppers are placed in all the five gaps 25 of each meander structure 1a, but a stopper may be placed in at least one of the five gaps of each meander structure 1a. In this case, the stoppers 81 or 131 may be omitted. However, as shown in Embodiments 2 and 4, when stoppers are placed in all the gaps 25, displacement of the meander structure 1a in the X-axis direction can be more reliably suppressed.

In Embodiments 1 and 2, as described with reference to FIG. 3, the height ranges of the stoppers 81 to 86 coincide with the height range of the coupling beam 35, but may include the height range of the coupling beam 35 and be wider than the height range of the coupling beam 35. In Embodiments 3 and 4, as described with reference to FIG. 11, the upper surfaces of the stoppers 131 to 136 are flush with the upper surface of the coupling beam 35, but may be positioned higher than the upper surface of the coupling beam 35. When each stopper is set wider than the height range of the coupling beam 35 as described above, displacement of the coupling beam 35 and the vibration plates 21 to 24 adjacent to the stoppers can be reliably suppressed.

In Embodiments 1 to 4, the structure 200 is separate from the optical reflective element 1, but may be included as a part of the optical reflective element 1.

In Embodiments 1 to 4, the structure 200 is placed below the fixation part 10, but may be placed above the fixation part 10. In this case, an opening penetrating up and down is formed in a portion of the structure 200 that is located above the mirror 70, such that light incident on the mirror 70 and reflected by the mirror 70 is not obstructed. In each of Embodiments 3 and 4, in the case where the structure 200 is placed above the fixation part 10, the stoppers 81 or 131 are formed so as to extend downward from the lower surface of the structure 200.

In Embodiments 1 to 4, the device layer 101 is made of Si, but may be made of another material. The drive parts 50 and 60 are configured to include a piezoelectric body as shown in FIG. 2, but may be configured by a mechanism or the like capable of vibrating the vibration plates 21 to 24. The materials forming the drive parts 50 and 60 are not limited to the materials described with reference to FIG. 2.

In Embodiments 1 to 4, the vibration plates 21 to 24 each have a rectangular shape that is longer in the Y-axis direction than in the X-axis direction, but may each have a rectangular shape that is longer in the X-axis direction than in the Y-axis direction, or may each have a square shape having equal lengths in the X-axis direction and the Y-axis direction.

In Embodiments 1 to 4, the pair of meander structures 1a (the vibration plates 21 to 24 and the connection parts 31 to 34), the pair of coupling beams 35, and the pair of stoppers are placed with the movable part 40 interposed therebetween. However, the present invention is not limited thereto, and the meander structure 1a, the coupling beam 35, and the stopper may be placed on only one of the X-axis positive side and the X-axis negative side of the movable part 40. In this case, a connection beam that connects the movable part 40 and the fixation part 10 and extends straight along the rotation axis R10 may be placed on the side opposite to the side on winch the meander structure 1a, the coupling beam 35, and the stopper are placed.

In addition to the above, various modifications can be made as appropriate to the embodiments of the present invention without departing from the scope of the technical idea defined by the claims.

What is claimed is:

1. An optical reflective element comprising:
a movable part having a mirror formed therein;
a fixation part supporting the movable part;
a meander-type vibration plate placed between the movable part and the fixation part;
a coupling beam coupling the vibration plate to the movable part;
a drive part placed on the vibration plate and configured to rotate the movable part about a rotation axis; and
a stopper placed adjacent to at least one of the vibration plate and the coupling beam in a direction parallel to the rotation axis and configured to restrict at least displacement of the vibration plate.

2. The optical reflective element according to claim 1, wherein the stopper is adjacent to a coupling position between the vibration plate and the coupling beam in the direction parallel to the rotation axis.

3. The optical reflective element according to claim 1, wherein
the coupling beam has higher rigidity than the vibration plate, and
the stopper is adjacent to the coupling beam in the direction parallel to the rotation axis.

4. The optical reflective element according to claim 3, wherein
the coupling beam has a portion extending in a direction intersecting the rotation axis, and
the stopper is adjacent to the portion of the coupling beam in the direction parallel to the rotation axis.

5. The optical reflective element according to claim 4, wherein the portion of the coupling beam extends in a direction substantially perpendicular to the rotation axis.

6. The optical reflective element according to claim 1, wherein the stopper is placed in at least one gap of a meander structure of the vibration plate in the direction parallel to the rotation axis.

7. The optical reflective element according to claim 6, wherein the stopper is placed in each of all gaps of the meander structure of the vibration plate in the direction parallel to the rotation axis.

8. The optical reflective element according to claim 1, wherein the stopper extends from a structure located above or below the optical reflective element.

9. The optical reflective element according to claim 8, wherein the structure is a member supporting the fixation part.

10. The optical reflective element according to claim 1, wherein the stopper extends from a structure surrounding the optical reflective element.

11. The optical reflective element according to claim 10, wherein the structure is the fixation part.

12. The optical reflective element according to claim 1, wherein
a pair of the vibration plates, a pair of the coupling beams, and a pair of the stoppers are placed with the movable part interposed therebetween, and
the drive part is placed on each of the pair of the vibration plates.
